(19) United States
(12) Patent Application Publication
(10) Pub. No.: US 2022/0402245 A1
(43) Pub. Date: Dec. 22, 2022

(54) ACTUATOR, METHOD FOR MANUFACTURING SAME, DRIVE DEVICE, AND ELECTRONIC DEVICE

(71) Applicant: SONY GROUP CORPORATION, TOKYO (JP)

(72) Inventors: SATOSHI NAKAMARU, TOKYO (JP); AKIHIRO NAKATA, TOKYO (JP); MICHIKO NAKAO, TOKYO (JP); YOSHIO GOTO, TOKYO (JP); TOMOMI YUKUMOTO, TOKYO (JP)

(21) Appl. No.: 17/754,319

(22) PCT Filed: Oct. 6, 2020
(86) PCT No.: PCT/JP2020/037846

§ 371 Date: Mar. 30, 2022

(30) Foreign Application Priority Data
Oct. 8, 2019 (JP) 2019-185390

(51) Int. Cl. B32B 25/04; B32B 7/12; B32B 3/08; B32B 3/26; B32B 25/20; B32B 7/022

(52) U.S. Cl. CPC B32B 25/042; B32B 7/12; B32B 3/08; B32B 3/266; B32B 25/20; B32B 7/022; B32B 2250/42; B32B 2250/44; B32B 2307/202; B32B 2307/204; B32B 2307/206; B32B 2307/732; B32B 2307/51; B32B 2457/00

(57) ABSTRACT

An actuator includes a plurality of laminated electrode sheets, and adhesive layers provided between the electrode sheets adjacent to each other. Each electrode sheet includes an elastomer layer, and an electrode provided on the elastomer layer. The plurality of electrode sheets are laminated such that the elastomer layer and the electrode are alternately located, and the adhesive layer is thinner than the electrode.

### TECHNICAL FIELD

The present disclosure relates to an actuator, a method for manufacturing the same, a drive device, and an electronic device.

### BACKGROUND ART

In recent years, polymer actuators that convert electrical energy into mechanical energy have become widely known. One such polymer actuator is a laminated type actuator in which electrodes and elastomer layers are alternately laminated (see, for example, PTL 1).

### CITATION LIST

### Patent Literature

[PTL 1]
WO 2016/031137

### SUMMARY

### Technical Problem

However, in the laminated type actuator, adhesion between the electrodes and the elastomer layers is poor. For this reason, the laminated type actuator has a low dielectric strength.

An object of the present disclosure is to provide an actuator capable of improving adhesion between an electrode and an elastomer layer, a method for manufacturing the same, a drive device, and an electronic device.

### Solution to Problem

In order to solve the problems described above, a first disclosure is an actuator including:

a plurality of laminated electrode sheets; and

adhesive layers provided between the electrode sheets adjacent to each other, wherein each of the electrode sheets includes:

an elastomer layer; and

an electrode provided on the elastomer layer,

the plurality of electrode sheets are laminated such that the elastomer layers and the electrodes are alternately located, and

the adhesive layer is thinner than the electrode.

A second disclosure is a drive device including the actuator of the first disclosure.

A third disclosure is an electronic device including the actuator of the first disclosure.

A fourth disclosure is a method for manufacturing an actuator, including:

forming an electrode on a first elastomer layer;

forming an adhesive layer on the electrode; and

bonding a second elastomer layer to the first elastomer layer with the adhesive layer,

wherein the adhesive layer is thinner than the electrode.

### BRIEF DESCRIPTION OF DRAWINGS

FIG. 1 is a cross-sectional view showing an example of a configuration of an actuator according to a first embodiment of the present disclosure.

FIGS. 2A, 2B, 2C, 2D, 2E, and 2F are process diagrams for describing an example of a method for manufacturing the actuator according to the first embodiment of the present disclosure.

FIGS. 3A and 3B are process diagrams for describing an example of the method for manufacturing the actuator according to the first embodiment of the present disclosure.

FIG. 4 is a cross-sectional view showing an example of a configuration of an actuator according to a modified example of the first embodiment of the present disclosure.

FIG. 5 is a cross-sectional view showing an example of a configuration of an actuator according to a modified example of the first embodiment of the present disclosure.

FIG. 6 is a cross-sectional view showing an example of a configuration of an actuator according to a modified example of the first embodiment of the present disclosure.

FIG. 7 is a perspective view showing an example of an exterior shape of an actuator according to a second embodiment of the present disclosure.

FIG. 8 is a cross-sectional view along line VIII-VIII in FIG. 7.

FIG. 9 is an exploded perspective view showing an example of a configuration of the actuator according to the second embodiment of the present disclosure.

FIG. 10 is a cross-sectional view showing an example of a configuration of an actuator according to a modified example of the second embodiment of the present disclosure.

FIG. 11 is an exploded perspective view showing an example of a configuration of an actuator according to a modified example of the second embodiment of the present disclosure.

FIG. 12 is a cross-sectional view showing an example of a configuration of a photographing device as an application example.

FIG. 13A is a plan view showing an example of a configuration of a lens and a holder for holding the lens. FIG. 13B is a cross-sectional view along line XIIIB-XIIIB in FIG. 13A.

FIG. 14 is an enlarged cross-sectional view showing region R in FIG. 13B.

FIG. 15 is a cross-sectional view showing an example of a configuration of a display device as an application example.

FIG. 16 is a cross-sectional view showing an example of a configuration of a multi-point tactile display as an application example.

FIG. 17 is a graph showing a relationship between an applied electric field and a generated stress of a dielectric elastomer actuator of Example 1.

### DESCRIPTION OF EMBODIMENTS

Embodiments and application examples of the present disclosure will be described in the following order. In addition, in all figures of the following embodiments and application examples, the same or corresponding portions will be denoted by the same reference numerals.

1. First embodiment (example of actuator)

2. Second embodiment (example of actuator)

3. Application example (example of photographing device)

4. Application example (example of display device)

5. Application example (example of multi-point tactile display)

### 1. First Embodiment

[Configuration of Actuator]

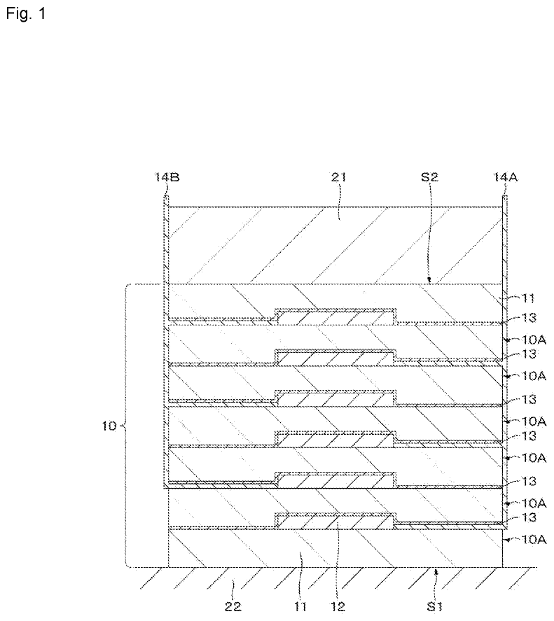

First, with reference to FIG. 1, an example of a configuration of an actuator 10 according to a first embodiment of the present disclosure will be described. The actuator 10 is a laminated type dielectric elastomer actuator (DEA). The actuator 10 has a rectangular sheet shape. The actuator 10 has a first main surface S1 and a second main surface S2 that face each other. Also, in the present disclosure, a sheet is defined to include a film as well.

The actuator 10 includes a plurality of electrode sheets 10A, adhesive layers 13, a lead-out electrode 14A, and a lead-out electrode 14B. Also, the lead-out electrodes 14A and 14B may or may not be provided depending on needs.

The actuator 10 is configured to be expandable and contractible in an in-plane direction of the actuator 10 by applying a voltage. That is, the actuator 10 is configured to be displaceable in a thickness direction of the actuator 10.

The actuator 10 can be applied to various drive devices or electronic devices. In this case, the actuator 10 is fixed on a base material 22 of a drive device or an electronic device. Further, a driven body 21 of the drive device or the electronic device is fixed on the actuator 10. The actuator 10 and the base material 22 are bonded by an adhesive (not shown), and the actuator 10 and the driven body 21 are bonded by an adhesive (not shown). Also, in the present disclosure, pressure sensitive adhesion is defined as a type of adhesion.

Specific examples of the drive device to which the actuator 10 can be applied include but are not limited to lens drive devices, image stabilizing devices, vibration devices (tactile displays, vibrators, and acoustic transducers (speakers, etc.)). Specific examples of the electronic device to which the actuator 10 can be applied include but are not limited to personal computers, mobile devices, mobile phones, tablet computers, display devices, photographing devices, audio devices, game devices, industrial tools, robots, and the like.

(Electrode Sheet)

The plurality of electrode sheets 10A are laminated to form a laminate. Each electrode sheet 10A includes an elastomer layer 11, and an electrode 12 provided on the elastomer layer 11. The plurality of electrode sheets 10A are laminated so that the elastomer layers 11 and the electrodes 12 are alternately located. From the viewpoint of an insulating property, the first and second main surfaces S1 and S2 of the actuator 10 are preferably covered with the elastomer layers 11.

(Elastomer Layer)

The elastomer layer 11 has elasticity in the in-plane direction of the actuator 10. Each elastomer layer 11 is sandwiched by a set of the electrodes 12. The elastomer layer 11 is a dielectric elastomer layer and is a sheet having a rectangular shape. The elastomer layer 11 contains, for example, an insulating elastomer serving as an insulating elastic material. The insulating elastomer includes, for example, at least one of acrylic rubber, silicone rubber, ethylene-propylene-diene terpolymer (EPDM), natural rubber (NR), butyl rubber (IIR), isoprene rubber (IR), acrylonitrile-butadiene copolymer rubber (NBR), hydrogenated acrylonitrile-butadiene copolymer rubber (H-NBR), hydrin-based rubber, chloroprene rubber (CR), fluororubber, urethane rubber, and the like.

The elastomer layer 11 may contain additives, if necessary. The additives are, for example, at least one of a cross-linking agent, a plasticizer, an anti-aging agent, a surfactant, a viscosity modifier, a reinforcing agent, a coloring agent, and the like.

(Electrode)

The electrode 12 has elasticity in the in-plane direction of the actuator 10. Thus, the electrode 12 can expand and contract in accordance with the expansion and contraction of the elastomer layer 11. The elastomer layer 11 is sandwiched between the electrodes 12 adjacent to each other in the thickness direction of the actuator 10. The electrodes 12 included in each electrode sheet 10A overlap each other in the thickness direction of the actuator 10. Examples of a shape of the electrode 12 include a polygonal shape such as a rectangular shape, a circular shape, an elliptical shape, and the like.

A ratio (D2/D1) of a thickness D2 of the electrode 12 to a thickness D1 of the elastomer layer 11 is preferably ½ or less, and more preferably 1/10 or more and ½ or less. When the ratio (D2/D1) exceeds ½, an amount of displacement is significantly reduced due to an influence of rigidity of the electrode 12. On the other hand, when the ratio (D2/D1) is less than 1/10, resistance of the electrode 12 increases and responsiveness thereof deteriorates.

The electrode 12 contains a conductive material. The conductive material is, for example, at least one of a conductive filler and a conductive polymer. Examples of a shape of the conductive filler include a spherical shape, an ellipsoidal shape, a needle shape, a plate shape, a scale shape, a tube shape, a wire shape, a rod shape, a fibrous shape, an irregular shape, and the like, but they are not particularly limited thereto. Also, a conductive filler having one type of the shape may be used, or conductive fillers having two or more types of the shape may be used in combination.

The conductive filler contains, for example, at least one of a carbon-based filler, a metal-based filler, a metal oxide-based filler, and a metal-coated filler. Here, the metal is defined to include semimetals.

The carbon-based filler includes, for example, at least one of carbon black (for example, Ketjen black, acetylene black, etc.), porous carbon, carbon fibers (for example, PAN-based, pitch-based, etc.), carbon nanofibers, fullerene, graphene, vapor-grown carbon fibers (VGCF), carbon nanotubes (for example, SWCNTs, MWCNTs, etc.), carbon microcoils, and carbon nanohorns.

The metal-based filler contains, for example, at least one of copper, silver, gold, platinum, palladium, nickel, tin, cobalt, rhodium, iridium, iron, ruthenium, osmium, manganese, molybdenum, tungsten, niobium, tantalum, titanium, bismuth, antimony, and lead.

The metal oxide-based filler includes, for example, indium tin oxide (ITO), zinc oxide, indium oxide, antimony-added tin oxide, fluorine-added tin oxide, aluminum-added zinc oxide, gallium-added zinc oxide, silicon-added zinc oxide, zinc oxide-tin oxide, indium oxide-tin oxide, or zinc oxide-indium oxide-magnesium oxide.

The metal coated filler is a base filler coated with a metal. The base filler is, for example, mica, glass beads, glass fibers, carbon fibers, calcium carbonate, zinc oxide or titanium oxide. The metal that coats the base filler includes, for example, at least one of Ni and Al.

The conductive polymer includes, for example, at least one of polyethylene dioxythiophene/polystyrene sulfonic acid (PEDOT/PSS), polyaniline, polyacetylene, and polypyrrole.

The electrode 12 may further contain at least one of a binder, a gel, a suspension, and an oil, if necessary. The binder has elasticity. The binder is preferably an elastomer. As the elastomer, one the same as that of the elastomer layer 11 can be exemplified.

The electrode 12 may further contain additives, if necessary. As the additives, ones the same as those of the elastomer layer 11 can be exemplified.

The electrode 12 may contain a composite material. The composite material includes, for example, at least one of a composite material made of an elastomer and at least one of a conductive polymer and a conductive filler, a composite material of an elastic ion-conductive material and an electrolyte, a composite material made of a polymer suspension (acrylic emulsion, etc.) and at least one of a conductive polymer and a conductive filler, a composite material made of a block copolymer and at least one of a conductive polymer and a conductive filler, and a composite material made of a polymer gel and an ionic conductor.

(Adhesive Layer)

The adhesive layer 13 is provided between the adjacent electrode sheets 10A, and the adjacent electrode sheets 10A are bonded together. The adhesive layer 13 provides adhesion between the elastomer layer 11 and the electrode 12 of the adjacent electrode sheets 10A. In order to improve the adhesion between the adjacent electrode sheets 10A, the adhesive layer 13 preferably covers the electrode 12, and more preferably covers the entire one main surface of the elastomer layer 11 provided with the electrode 12. The adhesive layer 13 is thinner than the electrode 12. Thus, a drive voltage of the actuator 10 can be reduced. The adhesive layer 13 preferably contains a silicone-based adhesive.

In order to improve the adhesion between the adjacent electrode sheets 10A (that is, the adhesion between the electrode 12 and the elastomer layer 11 of the adjacent electrode sheet 10A), it is preferable that the electrode 12 and the adhesive layer 13 contain the same kind of material, and it is more preferable that the elastomer layer 11, the adhesive layer 13 and the electrode 12 contain the same kind of material. In this case, the adhesive contained in the adhesive layer 13 and the binder contained in the electrode 12 may be made of the same material. The same kind of material is preferably a silicone-based material.

(Lead-Out Electrode)

The lead-out electrodes 14A and 14B preferably have elasticity. Thus, the lead-out electrodes 14A and 14B can expand and contract in accordance with the expansion and contraction of the actuator 10. Accordingly, the lead-out electrodes 14A and 14B can inhibit breakage or peeling from the elastomer layer 11 of the lead-out electrodes 14A and 14B due to the expansion and contraction of the actuator 10.

The lead-out electrodes 14A and 14B electrically connect the electrodes 12 of the laminated electrode sheets 10A and an external voltage source (not shown). The lead-out electrode 14A is connected to the electrodes 12 of the electrode sheets 10A that are located at odd number order positions when viewed from the first main surface S1 of the actuator 10 among the plurality of laminated electrode sheets 10A. The lead-out electrode 14B is connected to the electrodes 12 of the electrode sheets 10A that are located at even number order positions when viewed from the first main surface S1 of the actuator 10 among the plurality of laminated electrode sheets 10A. The lead-out electrode 14A and the lead-out electrode 14B are taken out from between the peripheral portions of the laminated electrode sheet 10A between the laminated elastomer layers 11. The lead-out electrodes 14A and 14B are led out from different positions on peripheral edges of the laminated electrode sheets 10A, for example, from opposite positions.

The lead-out electrodes 14A and 14B contain a conductive material. As the conductive material, the same material as that of the electrode 12 can be exemplified. The lead-out electrodes 14A and 14B may contain a binder having elasticity, if necessary. The binder is preferably an elastomer. As the elastomer, one the same as that of the elastomer layer 11 can be exemplified. The lead-out electrodes 14A and 14B have, for example, linear shapes.

[Operation of Actuator]

Next, an example of an operation of the actuator 10 according to the first embodiment of the present disclosure will be described.

When a drive voltage is applied between the electrodes 12, an attractive force due to Coulomb force acts between the adjacent electrodes 12 with the elastomer layer 11 interposed therebetween. For this reason, a portion of the elastomer layer 11 sandwiched between the electrodes 12 is compressed in the thickness direction and becomes thinner. Accordingly, a position of the second main surface S2, that is, a position of the driven body 21, is displaced downward. In the present specification, the term “downward” indicates a thickness direction of the actuator 10 from the second main surface S2 toward the first main surface S1.

On the other hand, when the drive voltage applied between the electrodes 12 adjacent to each other with the elastomer layer 11 interposed therebetween is released, the attractive force due to the Coulomb force does not act between the electrodes 12. For this reason, the portion of the elastomer layer 11 sandwiched between the electrodes 12 and 12 returns to the original thickness. Accordingly, the position of the first main surface S1, that is, the position of the driven body 21, is displaced upward and returned to the original position. In the present specification, the term “upward” indicates a thickness direction of the actuator 10 from the first main surface S1 toward the second main surface S2.

When the actuator 10 is applied to various drive devices or electronic devices, a default state (an initial state) of the actuator 10 may be a state in which a predetermined voltage is applied to the actuator 10 in advance or may be a state in which no voltage is applied to the actuator 10.

[Method for Manufacturing Actuator]

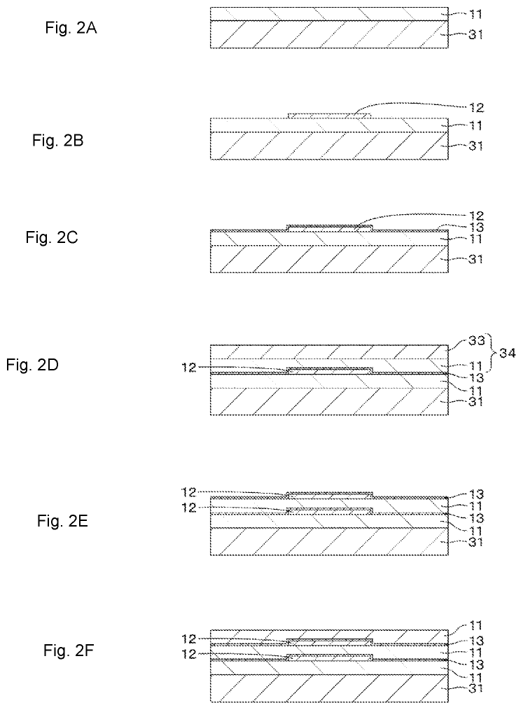

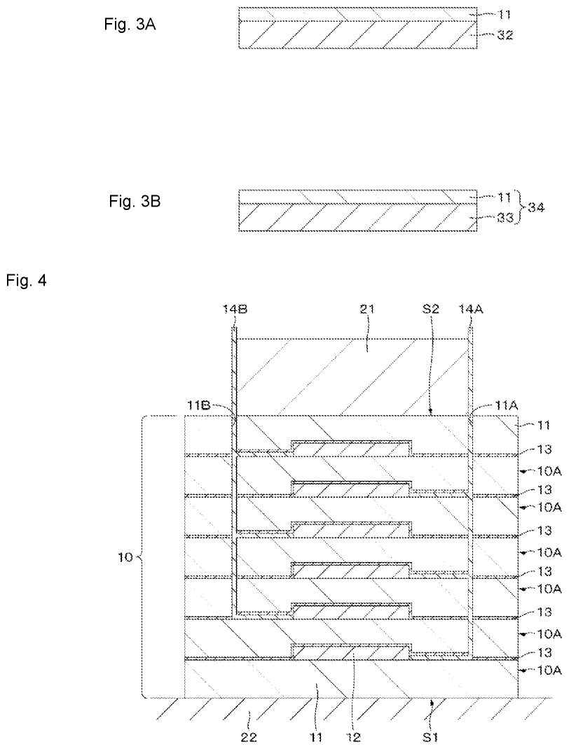

Next, an example of a method for manufacturing the actuator 10 according to the first embodiment of the present disclosure will be described with reference to FIGS. 2A to 2F, 3A, and 3B.

(Preparation Process of Pigment for Forming Elastomer Layer)

A pigment for forming the elastomer layer is prepared by adding an elastomer to a solvent and dispersing it. If necessary, a resin material other than the elastomer and at least one additive may be further added to the solvent. For example, for the purpose of improving coatability and pot life of the pigment for forming the elastomer layer on a base material (peeling base material), additives such as a surfactant, a viscosity modifier, and a dispersant may be added, if necessary. As a dispersion method, stirring, ultrasonic dispersion, bead dispersion, kneading, homogenizer treatment, or the like is preferably used.

The solvent is not particularly limited as long as it can disperse the elastomer. Examples of the solvent include, for example, water, ethanol, methyl ethyl ketone, isopropanol alcohol, acetone, anon (cyclohexanone and cyclopentanone), hydrocarbon (hexane), amide (DMF), sulfide (DMSO), butyl cellosolve, butyltriglycol, propylene glycol monomethyl ether, propylene glycol monoethyl ether, ethylene glycol monoethyl ether, ethylene glycol monopropyl ether, ethylene glycol monoisopropyl ether, diethylene glycol monobutyl ether, diethylene glycol monoethyl ether, diethylene glycol monomethyl ether, diethylene glycol diethyl ether, dipropylene glycol monomethyl ether, tripropylene glycol monomethyl ether, propylene glycol monobutyl ether, propylene glycol isopropyl ether, dipropylene glycol isopropyl ether, tripropylene glycol isopropyl ether, methyl glycol, terpineol, butyl carbitol acetate, and the like.

(Preparation Process of Conductive Pigment)

By adding a conductive material to a solvent and dispersing it, a conductive pigment which is a pigment for forming the electrode is prepared. If necessary, a binder and at least one additive may be further added to the solvent. For example, for the purpose of improving coatability and pot life of the conductive pigment on the elastomer layers 21A and 22A, additives such as a surfactant, a viscosity modifier, and a dispersant may be added, if necessary. The conductive pigment may be a conductive ink or a conductive paste. As a dispersion method, the same process as the above-mentioned preparation process of the pigment for forming the elastomer layer can be exemplified. Further, the solvent is not particularly limited as long as it can disperse the conductive material. For example, the same process as the above-mentioned preparation process of the pigment for forming the elastomer layer can be exemplified.

(Formation Process of Elastomer Layer (1))

First, as shown in FIG. 2A, the pigment for forming the elastomer layer is applied onto a base material 31 to form the elastomer layer 11.

(Formation Process of Electrode)

Next, as shown in FIG. 2B, the pigment for forming the electrode is applied onto the elastomer layer 11 to form the electrode 12. As a method for applying the pigment for forming the electrode (a method for forming the electrode 12), screen printing, intaglio printing or letterpress printing is preferable.

(Formation Process of Elastomer Layer (2))

Next, as shown in FIG. 3A, the elastomer layer 11 is formed on the base material 32 by applying the pigment for forming the elastomer layer, and then, as shown in FIG. 3B, the elastomer layer 11 is peeled off from the base material 32 and moved onto the base material 33. Thus, a laminate 34 is obtained. The base material 33 contains a fluororesin such as polytetrafluoroethylene (PTFE). For this reason, the elastomer layer 11 can be easily peeled off from the base material 33.

(Lamination Process)

Next, as shown in FIG. 2C, an uncured adhesive layer 13 is formed on the elastomer layer 11 on which the electrode 12 is formed. Next, as shown in FIG. 2D, the laminate 34 is placed on the adhesive layer 13 in an uncured state with the elastomer layer 11 of the laminate 34 on the adhesive layer 13 side, and then the adhesive layer 13 is cured by, for example, heat treatment. Thus, the laminate 34 is bonded to one main surface of the elastomer layer 11 on which the electrode 12 is formed. After the adhesive layer 13 is cured, the base material 33 is peeled off from the elastomer layer 11. Subsequently, as shown in FIGS. 2E and 2F, the above-mentioned formation process of the electrode and the above-mentioned formation process of the elastomer layer (2) are alternately repeated to form a laminate. Thus, the dielectric elastomer actuator 10 is obtained.

[Effects]

As described above, the actuator 10 according to the first embodiment includes the plurality of laminated electrode sheets 10A and the adhesive layers 13 provided between the adjacent electrode sheets. Thus, the adhesion between the adjacent electrode sheets 10A, that is, the adhesion between the electrode 12 and the elastomer layer 11 of the adjacent electrode sheets 10A, can be improved. Accordingly, dielectric strength of the actuator 10 can be improved.

Further, in the actuator 10 according to the first embodiment, the adhesive layer 13 is thinner than the electrode 12. As a result, the drive voltage of the actuator 10 can be reduced.

### MODIFIED EXAMPLES

### Modified Example 1

In the first embodiment described above, the case in which the lead-out electrodes 14A and 14B are led out from between peripheral portions of the laminated electrode sheets 10A has been described, but the configuration of the lead-out electrodes 14A and 14B is not limited thereto. For example, as shown in FIG. 4, the plurality of laminated electrode sheets 10A may have a hole portion 11A and a hole portion 11B that extend from the second main surface S2 in the thickness direction of the actuator 10, or the lead-out electrode 14A and the lead-out electrode 14B may be led out from the second main surface S2 to the outside via the hole portion 11A and the hole portion 11B, respectively.

### Modified Example 2

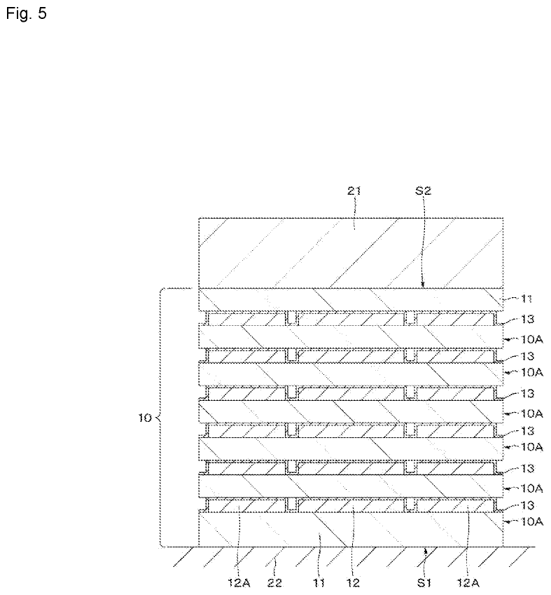

As shown in FIG. 5, the electrode sheet 10A may further include a dummy electrode (dummy layer) 12A provided on the elastomer layer 11. The dummy electrode 12A is provided around the electrode 12. The dummy electrode 12A preferably has elasticity in the in-plane direction of the actuator 10. Thus, the dummy electrode 12A can expand and contract in accordance with the expansion and contraction of the elastomer layer 11. The dummy electrode 12A may be made of the same material as the electrode 12 or may be made of a different material, but is preferably made of the same material as the electrode 12. In a case in which the dummy electrode 12A is made of the same material as the electrode 12, the electrode 12 and the dummy electrode 12A can be formed at the same time, and thus a manufacturing process of the actuator 10 can be simplified. In a case in which the dummy electrode 12A has conductivity, the electrode 12 and the dummy electrode 12A are separated from each other. A thickness of the dummy electrode 12A is preferably the same as or substantially the same as that of the electrode 12.

By providing the electrode sheet 10A with the dummy electrode 12A as described above, it is possible to inhibit generation of a step around the electrode 12. Accordingly, the adhesion between the adjacent electrode sheets 10A can be improved. In addition, since flatness of the elastomer layer 11 can be maintained, a high-quality actuator 10 can be provided.

### Modified Example 3

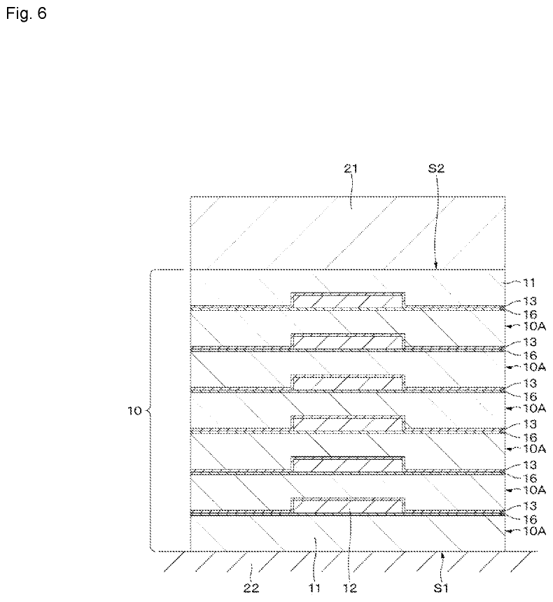

As shown in FIG. 6, the electrode sheet 10A may further include an adhesive layer 16 provided between the elastomer layer 11 and the electrode 12. A material of the adhesive layer 16 is the same as that of the adhesive layer 13 in the first embodiment. The electrode sheet 10A has the above-mentioned configuration, and thus the adhesion between the elastomer layer 11 and the electrode 12 that constitute the electrode sheet 10A can be improved. Accordingly, the dielectric strength of the actuator 10 can be further improved.

### Modified Example 4

In the first embodiment described above, the case in which the actuator 10 has a rectangular sheet shape has been described, but the shape of the actuator 10 is not limited thereto and may be a polygonal shape other than a rectangular shape, a circular shape, an elliptical shape, or the like.

### 2. Second Embodiment

[Configuration of Actuator]

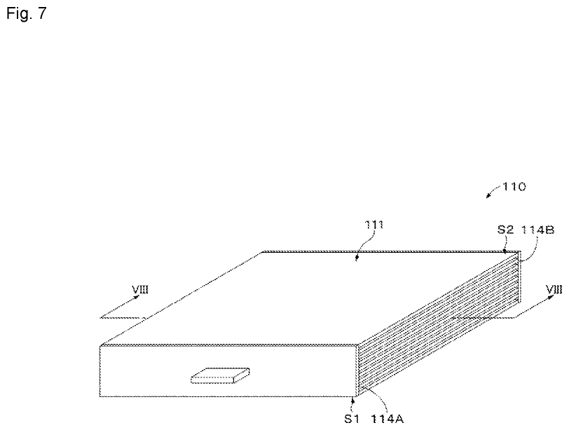

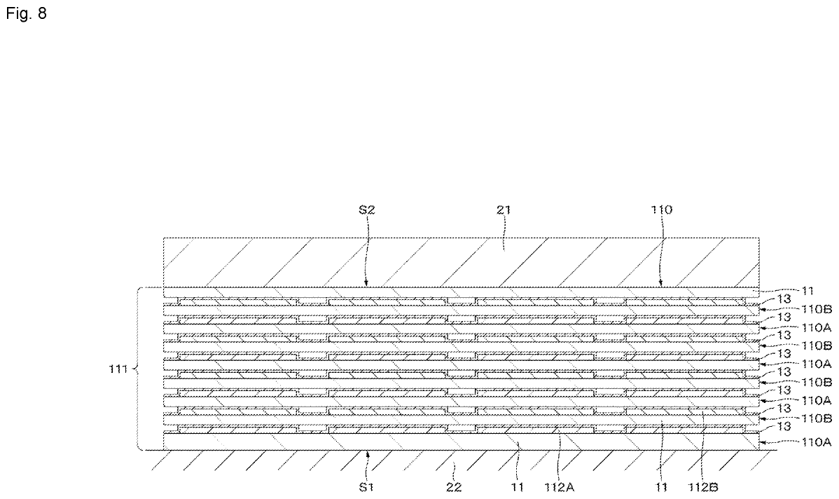

An example of a configuration of an actuator 110 according to a second embodiment of the present disclosure will be described with reference to FIGS. 7 to 9. The actuator 110 is a laminated dielectric elastomer actuator (DEA). The actuator 10 has a rectangular sheet shape. The actuator 110 has a first main surface S1 and a second main surface S2 that face each other. The actuator 110 includes a laminate 111, a lead-out electrode 114A, and a lead-out electrode 114B. The lead-out electrodes 114A and 114B may or may not be provided according to necessity. Also, in the second embodiment, the same parts as those in the first embodiment will be denoted by the same reference numerals, and description thereof will be omitted.

The lead-out electrodes 114A and 114B are electrically connected to a voltage source (not shown) via wiring (not shown). The actuator 110 is configured to be expandable and contractible in an in-plane direction of the actuator 110 by applying a voltage. That is, the actuator 110 is configured to be displaceable in a thickness direction of the actuator 110.

(Laminate)

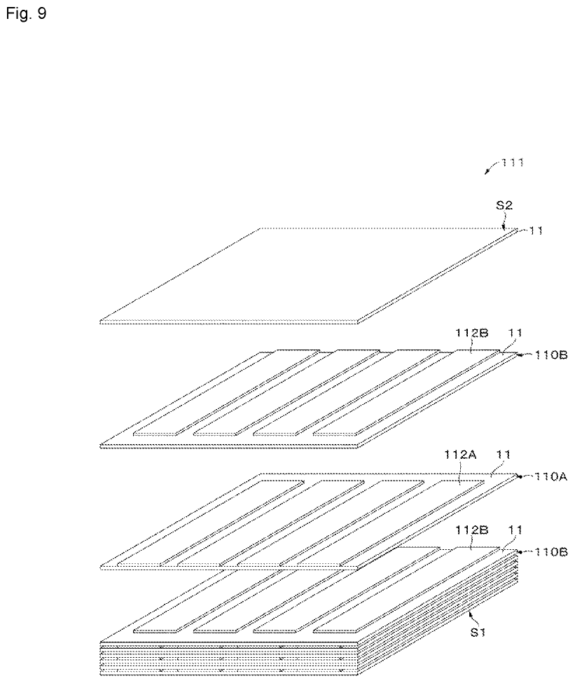

The laminate 111 includes a plurality of electrode sheets 110A, a plurality of electrode sheets 110B, and a plurality of adhesive layers 13. The plurality of electrode sheets 110A and the plurality of electrode sheets 110B are laminated so that the electrode sheets 110A and the electrode sheets 110A are alternately located to form the laminate 111. The adhesive layer 13 is provided between the electrode sheets 110A and 110B adjacent to each other. Each electrode sheet 110A includes an elastomer layer 11, and a plurality of electrodes 112A provided on the elastomer layer 11. Each electrode sheet 110B includes an elastomer layer 11, and a plurality of electrodes 112B provided on the elastomer layer 11. Also, in FIG. 9, the adhesive layer 13 is not shown. In the following description, in a case in which the electrode 112A and the electrode 112B are not particularly distinguished, they are referred to as an electrode 112.

The electrode 112A of the electrode sheet 110A and the elastomer layer 11 of the electrode sheet 110B face each other via the adhesive layer 13, and the electrode 112B of the electrode sheet 110B and the elastomer layer 11 of the electrode sheet 110A face each other via the adhesive layer 13. Each elastomer layer 11 is sandwiched between a set of the electrodes 112A and 112B. From the viewpoint of an insulating property, the first and second main surfaces S1 and S2 of the actuator 110 are preferably covered with the elastomer layer 11.

(Electrode)

The electrodes 112A and 112B have elasticity in the in-plane direction of the actuator 110. Thus, the electrodes 112A and 112B can expand and contract in accordance with the expansion and contraction of the elastomer layer 11. The plurality of electrodes 112A and the plurality of 112Bs are arranged in stripe shapes. The electrode 112B faces the electrode 112A. That is, the electrode 112A included in each electrode sheet 110A and the electrode 112B included in each electrode sheet 110B overlap each other in the thickness direction of the actuator 10. The electrode 112A is provided to extend to a first long side of the elastomer layer 11. The electrode 112B is provided to extend to a second long side of the elastomer layer 11. Thus, an end portion of the electrode 112A is exposed from a side surface of the actuator 110 on the first long side, and an end portion of the electrode 112B is exposed from a side surface of the actuator 110 on a second long side thereof.

The plurality of electrodes 112A are covered with the adhesive layers 13. Further, the plurality of electrodes 112B are covered with the adhesive layers 13. The adhesive layer 13 is thinner than the electrodes 112A and 112B. Thus, a drive voltage of the actuator 110 can be reduced.

Materials of the electrodes 112A and 112B are the same as the materials of the electrodes 12 in the first embodiment.

(Lead-Out Electrode)

The lead-out electrodes 114A and 114B preferably have elasticity. Thus, the lead-out electrodes 114A and 114B can expand and contract in accordance with the expansion and contraction of the actuator 110. Accordingly, it is possible to inhibit the lead-out electrodes 114A and 114B from peeling off from the side surfaces of the actuator 110 on the first and second long sides.

The lead-out electrode 114A is provided on the side surface of the actuator 110 on the first long side. The lead-out electrode 114A is in contact with the end portion of the electrode 112A exposed from the side surface of the actuator 110 on the first long side. The lead-out electrode 114B is provided on the side surface of the actuator 110 on the second long side. The lead-out electrode 114B is in contact with the end portion of the electrode 112B exposed from the side surface of the actuator 110 on the second long side.

The lead-out electrodes 114A and 114B contain a conductive material. As the conductive material, the same material as that of the electrode 12 in the first embodiment can be exemplified. The lead-out electrodes 114A and 114B may contain a binder having elasticity, if necessary. The binder is preferably an elastomer. As the elastomer, the same material as that of the elastomer layer 11 in the first embodiment can be exemplified.

[Effects]

As described above, the actuator 110 according to the second embodiment includes the plurality of electrode sheets 110A and electrode sheets 110B that are alternately laminated, and the adhesive layers 13 provided between the adjacent electrode sheets 110A and 110B. Thus, adhesion between the adjacent electrode sheets 110A and 110B, that is, adhesion between the electrode 112A of the electrode sheet 110A and the elastomer layer 11 of the electrode sheet 110B, and adhesion between the electrodes 112B of the electrode sheet 110B and the elastomer layer 11 of the electrode sheet 110A, can be improved. Accordingly, dielectric strength of the actuator 110 can be improved.

### MODIFIED EXAMPLES

### Modified Example 1

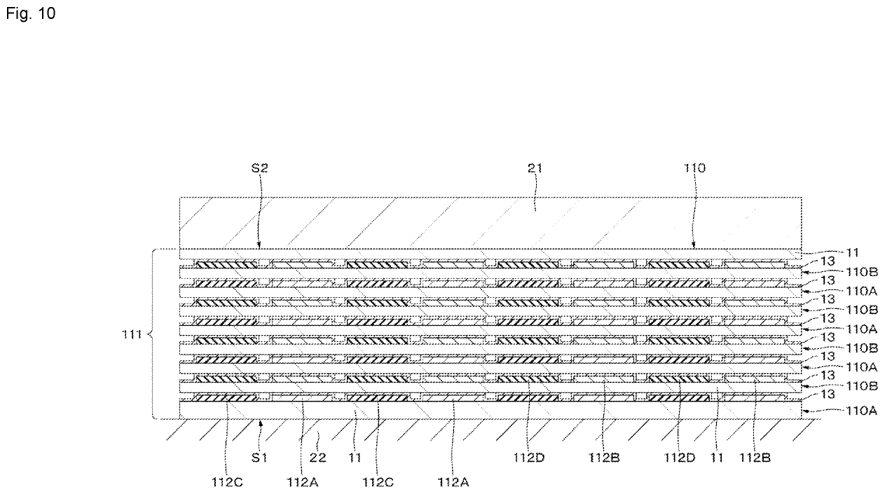

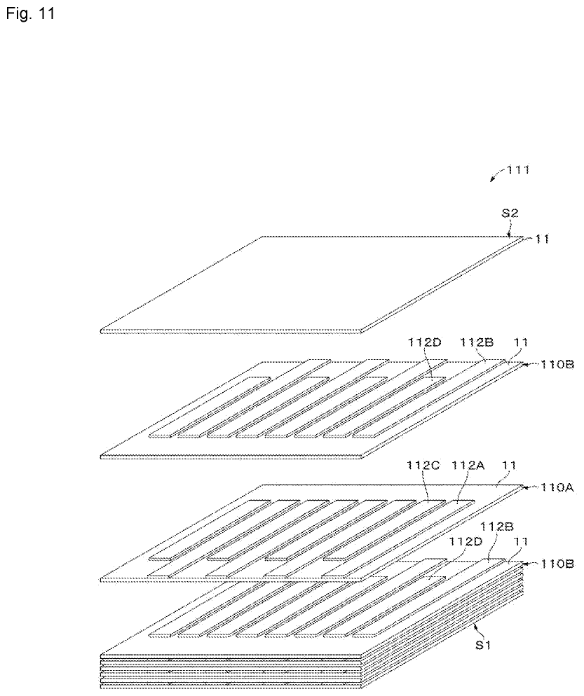

As shown in FIGS. 10 and 11, the electrode sheet 110A may further include a plurality of dummy electrodes 112C, and the electrode sheet 110B may further include a plurality of dummy electrodes 112D. The dummy electrodes 112C and 112D have elasticity in the in-plane direction of the actuator 110. Thus, the dummy electrodes 112C and 112D can expand and contract in accordance with the expansion and contraction of the elastomer layer 11.

The dummy electrodes 112C are provided in gaps between the adjacent electrodes 112A on the elastomer layer 11. The plurality of dummy electrodes 112C are arranged in stripe shapes on one main surface of the elastomer layer 11. The dummy electrodes 112D are provided in gaps between the adjacent electrodes 112B on the elastomer layer 11. The plurality of dummy electrodes 112C are arranged in stripe shapes on one main surface of the elastomer layer 11.

As described above, the electrode sheet 110A further includes the plurality of dummy electrodes 112C, and the electrode sheet 110B further includes the plurality of dummy electrodes 112D, and thus it is possible to inhibit generation of a step in the gap portion between the electrodes 112A and the gap portion between the electrodes 112B. Accordingly, the adhesion between the adjacent electrode sheets 110A and 110B can be further improved. In addition, since flatness of the elastomer layer 11 can be improved, a high-quality actuator 10 can be provided.

### Modified Example 2

In the second embodiment described above, the case in which the plurality of electrodes 112A and 112B are arranged in stripe shapes has been described, but an arrangement form of the plurality of electrodes 112A and 112B is not limited thereto, and they may be arranged in mesh shapes, grid shapes, dot shapes, meandering shapes, radial shapes, geometric pattern shapes, meandering shapes, concentric shapes (for example, concentric circle shapes), spiral shapes, spider web shapes, tree shapes, fish bone shapes, net shapes, or the like.

### 3. Application Example

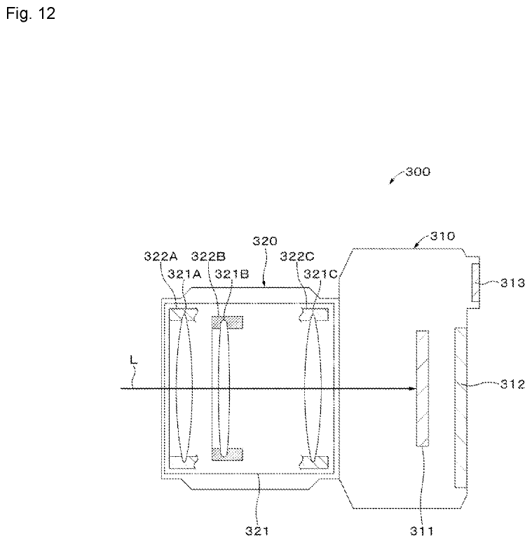

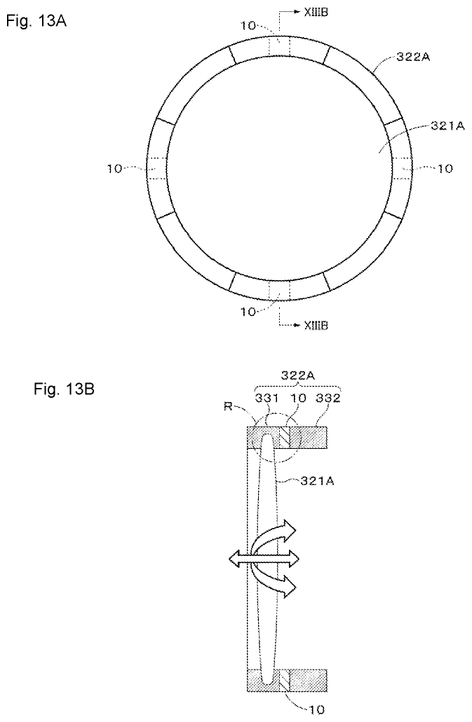

FIG. 12 is a cross-sectional view showing an example of a configuration of a photographing device 300 as an application example. The photographing device 300 is a so-called single-lens reflex camera and includes a camera body 310 and a photographing lens 320 that is configured to be attachable to and detachable from the camera body. The photographing device 300 is an example of an electronic device.

(Camera Body)

The camera body 310 includes an imaging element 311, a monitor 312, an electronic viewfinder 313, and the like. The imaging element 311 photoelectrically converts a subject light image formed by incident light L passing through the photographing lens 320 to generate a captured image signal. The imaging element 311 is configured of, for example, a CCD image sensor or a CMOS image sensor.

The captured image signal output from the imaging element 311 is subjected to image processing such as resolution conversion performed by an image processing unit (not shown) and displayed on the monitor 312 and the electronic viewfinder 313. Further, when a shutter button is pressed, the captured image signal is subjected to compression processing and recording encoding processing and then stored in a recording medium (not shown).

The monitor 312 and the electronic viewfinder 313 are configured of a display device such as an organic electro-luminescence (EL) display or a liquid crystal display.

(Photographing Lens)

The photographing lens 320 includes a lens optical system 321, and a lens control unit (not shown). The lens optical system 321 includes a plurality of lenses 321A, 321B, and 321C, a plurality of holders (support members) 322A, 322B, 322C, and the like that support these lenses 321A, 321B, and 321C. The holder 322A includes a plurality of actuators 10 according to the first embodiment or the modified examples thereof and supports the lens 321A via these actuators 10. However, the holder 322A may include the actuator 110 according to the second embodiment or the modified examples thereof instead of the actuator 10 according to the first embodiment or the modified examples thereof.

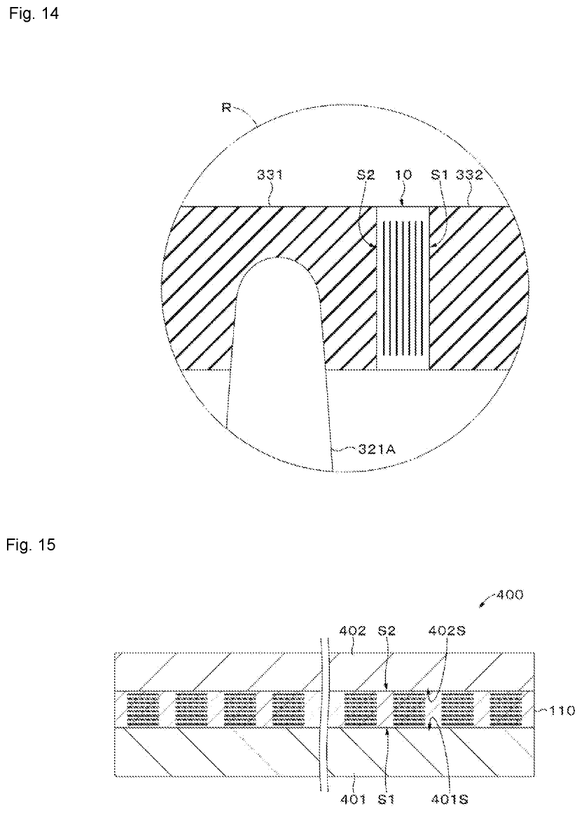

FIG. 13A is a plan view showing examples of configurations of the lens 321A and the holder 322A that holds the lens 321A. FIG. 13B is a cross-sectional view along line XIIIB-XIIIB in FIG. 13A. FIG. 14 is an enlarged cross-sectional view showing region R in FIG. 13B. The lens 321A is an autofocus lens. The holder 322A includes a lens support portion 331, a plurality of actuators 10, and a holder body 332.

The lens support portion 331 has a ring shape. The lens support portion 331 supports the lens 321A on an inner circumferential surface thereof. A driven body is configured of the lens support portion 331 and the lens 321A. The holder body 332 has a ring shape. The holder body 332 supports the lens support portion 331 via the plurality of actuators 10. The holder body 332 is an example of a base material that supports the driven body configured of the lens support portion 331 and the lens 321A.

The actuator 10 is an autofocus actuator. The actuator 10 moves the lens 321A in an optical axis direction of the incident light L. The second main surface S2 of the actuator 10 is fixed to the lens support portion 331. The first main surface S1 of the actuator 10 is fixed to the holder body 332.

The lens 321C is an image stabilizing lens. The holder 322C includes an image stabilizing actuator (not shown). The image stabilizing actuator moves the lens 321C in a plane perpendicular to the optical axis of the incident light L.

The lens control unit controls the autofocus actuator 10 and the image stabilizing actuator.

### 4. Application Example

FIG. 15 is a cross-sectional view showing an example of a configuration of a display device 400 as an application example. The display device 400 is a so-called flat speaker and includes a back chassis 401, a display panel 402, the actuator 110 according to the second embodiment or the modified examples thereof, a control unit (not shown), and the like. Also, the display device 400 may include a plurality of actuators 10 according to the first embodiment or the modified examples thereof instead of the actuator 110 according to the second embodiment or the modified examples thereof. The display device 400 is an example of an electronic device or a drive device.

The back chassis 401 is an example of the base material that supports the actuator 110 and constitutes a back surface of the display device 400. The back chassis 401 is provided on the first main surface S1 of the actuator 110. The back chassis 401 has a support surface 401S that faces the display panel 402.

The display panel 402 is an example of the driven body driven by the actuator 110 and is, for example, an organic EL panel or a liquid crystal panel. The display panel 402 is provided on the second main surface S2 of the actuator 110. The display panel 402 has a back surface 402S that faces the back chassis 401.

The first main surface S1 of the actuator 110 is fixed to the support surface 401S. The second main surface S2 of the actuator 110 is fixed to the back surface 402S. The actuator 110 drives the display panel 402 to emits a plane wave (sound wave). The control unit controls drive of the display panel 402 and the actuator 110.

### 5. Application Example

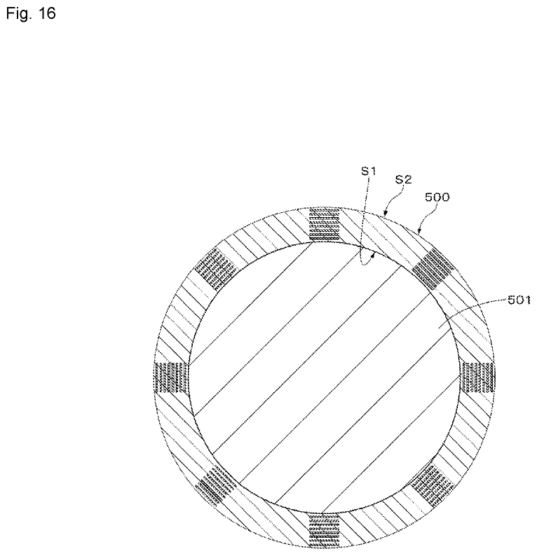

FIG. 16 is a cross-sectional view showing an example of a configuration of a multi-point tactile display 500 as an application example. The multi-point tactile display 500 is similar to the actuator 110 according to the second embodiment or the modified examples thereof, except that it has a tubular shape. The multi-point tactile display 500 is an example of a drive device.

An inner circumferential surface S1 of the multi-point tactile display 500 is attached to a human body portion 501. Examples of the human body portion 501 to which the multi-point tactile display 500 is attached include, but not limited to, an arm, a leg, a finger, and the like.

### EXAMPLES

Hereinafter, the present disclosure will be specifically described with reference to examples, but the present disclosure is not limited to these examples.

### Example 1

(Formation Process of Elastomer Layer (1))

First, a two liquid mixture-based addition polymerization type silicone material was stirred and defoamed in a vacuum state, and then applied onto a base material (a PET sheet (an overhead projector (OHP) sheet)) by a film applicator to form an elastomer layer having a square sheet shape.

(Forming Process of Electrode)

Next, a pigment for forming the electrode having the following composition was prepared and printed on the elastomer layer by a screen printing machine to form a square-shaped electrode.

<Composition of Pigment for Forming Electrode>

Addition polymerization type silicone material (manufactured by Toray Dow Corning Co., Ltd., MS-1003): 4 parts by mass Acetylene Black (manufactured by Denka Co., Ltd., Li-100): 0.8 parts by mass Methylsiloxane (manufactured by Dow Corning Co., Ltd., OS-10): 36 parts by mass

(Forming Process of Elastomer Layer (2))

Next, the elastomer layer was formed on the base material (PET sheet (overhead projector (OHP) sheet)) in the same manner as in the above-mentioned process for forming the elastomer layer (1), and then the elastomer layer was peeled off from the base material and transferred onto a polytetrafluoroethylene (PTFE) sheet. Thus, a sheet laminate was obtained.

(Lamination Process)

Next, on the elastomer layer on which the electrode was formed, the same addition polymerization type silicone material (manufactured by Toray Dow Corning Co., Ltd., MS-1003) as the silicone binder of the electrode was thinly applied once on the entire surface to form an uncured adhesive layer. Next, the sheet laminate was placed on the uncured adhesive layer so that the elastomer layer of the sheet laminate faced the electrode, and then the adhesive layer was cured under the condition of 110° C. Thus, the elastomer layer of the sheet laminate was bonded to one main surface of the elastomer layer on which the electrode was formed. After curing, the PTFE sheet was peeled off from the elastomer layer. Subsequently, the formation process of the electrode and the formation process of the elastomer layer (2) are alternately repeated, and a total of 7 layers of elastomer layer/electrode/elastomer layer/electrode/elastomer layer/electrode/elastomer layer were formed. Thus, the aimed dielectric elastomer actuator was obtained.

### Comparative Example 1

The dielectric elastomer actuator was obtained in the same manner as in Example 1 except that formation of the adhesion layer was omitted in the lamination process.

[Evaluation]

(Thickness of Elastomer Layer)

Thicknesses of the elastomer layers of Example 1 and Comparative Example 1 were measured from the observation photograph of the cross section. Here, the thickness of the elastomer layer indicates a thickness (initial thickness) thereof in a state in which the actuator is not stretched. In addition, it was confirmed that the electrode and the elastomer layer were separated.

(Adhesion)

A peeling test was performed on the actuators of Example 1 and Comparative Example 1 by a cross-cut test of 25 masses in accordance with JIS-K-5600. As a result, the following was found. In the dielectric elastomer layer of Comparative Example 1 which does not include an adhesive layer between the elastomer layer and the electrode, many elastomer layers are peeled off at the electrode portion (between the elastomer layer and the electrode). On the other hand, in the actuator (Example 1) including the adhesive layer between the elastomer layer and the electrode, many elastomer layers were peeled off in the base material (PET sheet surface) serving as an underlayer. Accordingly, in the actuator including the adhesive layer between the elastomer layer and the electrode, higher adhesion between the elastomer layer and the electrode can be obtained as compared with the actuator that does not include an adhesive layer between the elastomer layer and the electrode.

(Breakdown Dielectric Strength)

A breakdown dielectric strength of the actuator of Example 1 was measured as follows. The breakdown dielectric strength is determined by measuring an applied electric field strength when the elastomer layer of the actuator with an area of 4 cm×4 cm breaks down in a case in which the electric field strength is increased at a pace of 10 sec per 1 V/μm. The breakdown was determined by lighting of an overload lamp of a high voltage generator (manufactured by NF Circuit Design Block Co., Ltd., HVA4321).

(Electrostatic Capacitance)

In order to confirm whether the electrode was properly formed, electrostatic capacitance of the actuator of Example 1 was measured. The electrostatic capacitance was measured under the condition of 100 Hz using an LCR meter manufactured by NF Circuit Design Block Co. Ltd. As a result, as shown in Table 1, an electrostatic capacitance of 2.54 nF was obtained. This electrostatic capacitance was substantially the same as an electrostatic capacitance (2.5 nF) calculated by calculation for the actuator of Example 1. From this result, it is considered that the electrode is appropriately formed in the actuator of the first embodiment produced this time.

(Generated Stress)

A generated stress of the actuator of Example 1 was measured as follows. The actuator was fixed to a universal tester Autograph AGS-X manufactured by Shimadzu Corporation, and a force generated in a load cell when an electric field was applied under the condition of being stretched 1.1 times in a uniaxial direction was defined as the generated stress.

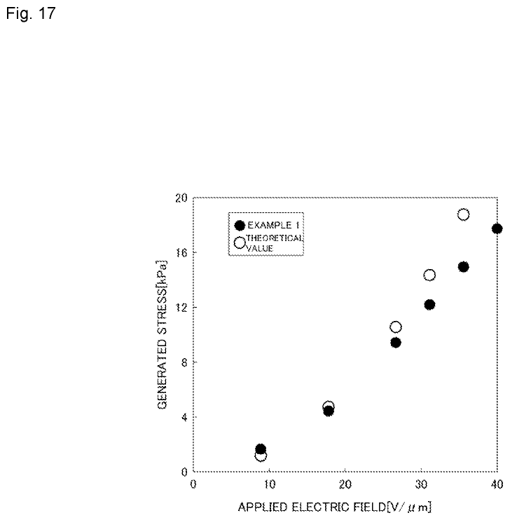

FIG. 17 shows a relationship between the applied electric field and the generated stress. FIG. 17 also shows a theoretical value calculated by assuming that a damping coefficient due to a rectangular structure is 0.6. From FIG. 17, it can be confirmed that a result almost equal to the theoretical value has been obtained. Almost no loss, or the like, which seems to be caused by an interface between the elastomer layer and the electrode, was observed. As the electric field strength increases, a deviation between the measured value and the theoretical value tends to increase, which is considered to be due to the effect of buckling.

Table 1 shows configurations and evaluation results of the actuators of Example 1 and Comparative Example 1.

TABLE 1

| | Configuration of actuator | | | | | | | |
|---|---|---|---|---|---|---|---|---|
| | Thickness | | | | | | | |
| | of | Number | Thickness | | Presence | | Breakdown | Electro |
| | elastomer | of | of | Number | of | | dielectric | static |
| | layer | elastomer | electrode | of | adhesive | Stretching | strength | capacitance |
| | [um] | layer | [um] | electrode | layer | magnification | [V/μm] | [nF] |
| Example 1 | 42 | 4 | 3.8 | 3 | Yes | 1.0 | 91 | 2.54 |
| Comparative | 42 | 4 | 3.8 | 3 | No | 1.0 | — | — |
| example 1 | | | | | | | | |

Table 2 shows evaluation results of the actuator of Example 1.

TABLE 2

| | | | Stress measurement Test | |
|---|---|---|---|---|
| | | Electrostatic | Generated | Applied |
| | Stretching | capacitance | stress | electric field |
| | magnification | [nF] | [kPa] | [V/μm] |
| Example 1 | 1.1 | 2.48 | 1.7 | 8.9 |
| | | | 4.4 | 17.8 |
| | | | 9.4 | 26.7 |
| | | | 12.2 | 31.1 |
| | | | 15.0 | 35.6 |
| | | | 17.8 | 40.0 |
| | | | 19.4 | 44.4 |
| | | | 24.4 | 48.9 |
| | | | 26.1 | 53.3 |

In Tables 1 and 2, the stretching ratio is a ratio (L1/L0) of a length L1 per a side of a stretched actuator to a length L0 per a side of an unstretched actuator.

The embodiments and the modified examples of the present disclosure have been specifically described above, but the present disclosure is not limited to the above-described embodiments and the modified examples, and various modifications based on the technical idea of the present disclosure are can be made. For example, the configurations, methods, processes, shapes, materials, numerical values, and the like given in the above-described embodiments and modified examples are merely examples, and different configurations, methods, processes, shapes, materials, numerical values, and the like may be used, if necessary. The configurations, methods, processes, shapes, materials, numerical values, and the like in the embodiments and modified examples described above can be combined with each other without departing from the gist of the present disclosure. Unless otherwise specified, the materials exemplified in the above-described embodiments and modified examples can be used alone or in combination of two or more.

Further, the present disclosure can also adopt the following configurations.

(1)

An actuator comprising:

a plurality of laminated electrode sheets; and

adhesive layers provided between the electrode sheets adjacent to each other,

wherein each electrode sheet includes;

an elastomer layer; and

an electrode provided on the elastomer layer,

the plurality of electrode sheets are laminated so that the elastomer layer and the electrode are alternately located, and

the adhesive layer is thinner than the electrode.

(2)

The actuator according to (1), wherein a ratio (D2/D1) of a thickness D2 of the electrode to a thickness D1 of the elastomer layer is ½ or less.

(3)

The actuator according to (1) or (2), wherein the electrode and the adhesive layer contain the same kind of material.

(4)

The actuator according to (1) or (2), wherein the elastomer layer, the electrode and the adhesive layer contain the same kind of material.

(5)

The actuator according to (3) or (4), wherein the same kind of material is a silicone-based material.

(6)

The actuator according to any one of (1) to (5), wherein the adhesive layer covers the electrode.

(7)

The actuator according to any one of (1) to (6), wherein the electrode sheet further includes an adhesive layer provided between the elastomer layer and the electrode.

(8)

The actuator according to any one of (1) to (7), further comprising a first lead-out electrode and a second lead-out electrode,

wherein the first lead-out electrode is connected to the electrodes of the electrode sheets located at odd number order positions when viewed from one main surface of the actuator among the plurality of laminated electrode sheets,

the second lead-out electrode is connected to the electrodes of the electrode sheets located at even number order positions when viewed from one main surface of the actuator among the plurality of laminated electrode sheets, and

the first lead-out electrode and the second lead-out electrode are led out from between peripheral portions of the laminated electrode sheets.

(9)

The actuator according to any one of (1) to (7), further comprising a first lead-out electrode and a second lead-out electrode,

wherein the first lead-out electrode is connected to the electrodes of the electrode sheets located at odd number order positions when viewed from one main surface of the actuator among the plurality of laminated electrode sheets,

the second lead-out electrode is connected to the electrodes of the electrode sheets located at even number order positions when viewed from one main surface of the actuator among the plurality of laminated electrode sheets,

the plurality of laminated electrode sheets have a first hole portion and a second hole portion that extend in the thickness direction of the actuator, and

the first lead-out electrode and the second lead-out electrode are led out to the outside through the first hole portion and the second hole portion.

(10)

The actuator according to any one of (1) to (9), wherein the electrode sheet further includes a dummy electrode provided on the elastomer layer.

(11)

A drive device comprising the actuator according to any one of (1) to (10).

(12)

An electronic device comprising the actuator according to any one of (1) to (10).

(13)

A method for manufacturing an actuator, comprising:

forming an electrode on a first elastomer layer;

forming an adhesive layer on the electrode; and

bonding a second elastomer layer to the first elastomer layer with the adhesive layer,

wherein the adhesive layer is thinner than the electrode.

(14)

The method for manufacturing the actuator according to (13), wherein a formation method of the electrode is screen printing, intaglio printing, or letterpress printing.

### REFERENCE SIGNS LIST

10, 110 Actuator
11 Elastomer layer
11A, 11B Hole portion
12, 112A, 112B Electrode
13 Adhesive layer
14A, 14B Lead-out electrode
12A, 112C, 112D Dummy electrode
111 Laminate
300 Photographing device (electronic device)
400 Display device (electronic device or drive device)
500 Multi-point tactile display (drive device)
S1 First main surface
S2 Second main surface

1. An actuator comprising:
a plurality of laminated electrode sheets; and
adhesive layers provided between the electrode sheets adjacent to each other,
wherein each electrode sheet incudes:
an elastomer layer; and
an electrode provided on the elastomer layer,
the plurality of electrode sheets are laminated so that the elastomer layer and the electrode are alternately located, and
the adhesive layer is thinner than the electrode.

2. The actuator according to claim 1, wherein a ratio (D2/D1) of a thickness D2 of the electrode to a thickness D1 of the elastomer layer is ½ or less.

3. The actuator according to claim 1, wherein the electrode and the adhesive layer contain the same kind of material.

4. The actuator according to claim 1, wherein the elastomer layer, the electrode and the adhesive layer contain the same kind of material.

5. The actuator according to claim 3, wherein the same kind of material is a silicone-based material.

6. The actuator according to claim 1, wherein the adhesive layer covers the electrode.

7. The actuator according to claim 1, wherein the electrode sheet further includes an adhesive layer provided between the elastomer layer and the electrode.

8. The actuator according to claim 1, further comprising a first lead-out electrode and a second lead-out electrode,
wherein the first lead-out electrode is connected to the electrodes of the electrode sheets located at odd number order positions when viewed from one main surface of the actuator among the plurality of laminated electrode sheets, the second lead-out electrode is connected to the electrodes of the electrode sheets located at even number order positions when viewed from one main surface of the actuator among the plurality of laminated electrode sheets, and
the first lead-out electrode and the second lead-out electrode are led out from between peripheral portions of the laminated electrode sheets.

9. The actuator according to claim 1, further comprising a first lead-out electrode and a second lead-out electrode,
wherein the first lead-out electrode is connected to the electrodes of the electrode sheets located at odd number order positions when viewed from one main surface of the actuator among the plurality of laminated electrode sheets,
the second lead-out electrode is connected to the electrodes of the electrode sheets located at even number order positions when viewed from one main surface of the actuator among the plurality of laminated electrode sheets,
the plurality of laminated electrode sheets have a first hole portion and a second hole portion that extend in the thickness direction of the actuator, and
the first lead-out electrode and the second lead-out electrode are led out to the outside through the first hole portion and the second hole portion.

10. The actuator according to claim 1, wherein the electrode sheet further includes a dummy electrode provided on the elastomer layer.

11. A drive device comprising the actuator according to claim 1.

12. An electronic device comprising the actuator according to claim 1.

13. A method for manufacturing an actuator, comprising:
forming an electrode on a first elastomer layer;
forming an adhesive layer on the electrode; and
bonding a second elastomer layer to the first elastomer layer with the adhesive layer,
wherein the adhesive layer is thinner than the electrode.

14. The method for manufacturing the actuator according to claim 13, wherein a formation method of the electrode is screen printing, intaglio printing, or letterpress printing.
